(19) United States
(12) Patent Application Publication
(10) Pub. No.: US 2014/0214347 A1
(43) Pub. Date: Jul. 31, 2014

(54) METHOD TO DETECT OPEN-CIRCUIT VOLTAGE SHIFT THROUGH OPTIMIZATION FITTING OF THE ANODE ELECTRODE HALF-CELL VOLTAGE CURVE

(71) Applicant: GM GLOBAL TECHNOLOGY OPERATIONS LLC, Detroit, MI (US)

(72) Inventors: Patricia M. Laskowsky, Ann Arbor, MI (US); Patrick Frost, Novi, MI (US); Brian J. Koch, Berkley, MI (US)

(73) Assignee: GM GLOBAL TECHNOLOGY OPERATIONS LLC, DETROIT, MI (US)

(21) Appl. No.: 13/756,327

(22) Filed: Jan. 31, 2013

(51) Int. Cl. G01R 31/36; G06F 17/00

(52) U.S. Cl. CPC G01R 31/3624; G06F 17/00
USPC 702/63

(57) ABSTRACT

Methods are disclosed for modeling changes in capacity and the state of charge vs. open circuit voltage (SOC-OCV) curve for a battery cell as it ages. During battery pack charging, voltage and current data are gathered for a battery cell. In one method, using multiple data points taken during the plug-in charge event, data optimization is used to determine values for two parameters which define a scaling and a shifting of the SOC-OCV curve from its original shape at the cell's beginning of life to its shape in the cell's current condition. In a second method, only initial and final voltages and current throughput data are needed to determine the values of the two parameters. With the scaling and shifting parameters calculated, the cell's updated capacity and updated SOC-OCV curve can be determined. The methods can also be applied to data taken during a discharge event.

### BACKGROUND OF THE INVENTION

1. Field of the Invention

This invention relates generally to state of charge determination of cells in a battery pack and, more particularly, to a method for modeling changes in the state of charge vs. open circuit voltage curve for battery cells as the cells age, where scaling and shifting of the curve are modeled using parameter regression or optimization applied to data from a plug-in charge, and the resulting cell performance curve is used to improve state of charge determination and capacity estimation.

2. Discussion of the Related Art

Electric vehicles and gasoline-electric or diesel-electric hybrid vehicles are rapidly gaining popularity in today's automotive marketplace. Electric and hybrid-electric vehicles offer several desirable features, such as reducing or eliminating emissions and petroleum-based fuel consumption at the consumer level, and potentially lower operating costs. A key subsystem of electric and hybrid-electric vehicles is the battery pack, which plays a large part in dictating the vehicle's performance. Battery packs in these vehicles typically consist of numerous interconnected cells, which are able to deliver a lot of power on demand. Maximizing battery pack performance and life are key considerations in the design and operation of electric and hybrid electric vehicles.

A typical electric vehicle battery pack includes two or more battery pack sections, with each section containing many individual battery cells as needed to provide the required voltage and capacity. In order to optimize the performance and durability of the battery pack, it is important to monitor the capacity and the state of charge of the cells. State of charge of a cell is typically determined based on the open circuit voltage of the cell, using a relationship which is defined in the form of a state of charge vs. open circuit voltage (SOC-OCV) curve. However, as battery cells age, experiencing repeated charge-discharge cycles, capacity typically fades, and the relationship between open circuit voltage and state of charge changes. While it is possible to disregard the capacity fade and the change in state of charge as a function of open circuit voltage in aging battery cells, for example by using a conservatively low estimate of capacity and state of charge during vehicle operation, it is far preferable to accurately determine capacity and state of charge of battery cells as they age. The accurate determination of capacity, and of state of charge as a function of open circuit voltage, is important both during charging of the battery pack and during discharging as the vehicle is driven.

Various methods of characterizing performance changes in aging battery cells are known in the art. Many of these methods are empirically-based; that is, they predict changes in the battery cell's performance based on the number of charge-discharge cycles, using average data from experimental measurements. Others of these methods simply estimate capacity fade, or reduction in energy storage capacity over time, but do not attempt to characterize the changes in the SOC-OCV curve. However, it is possible and desirable to estimate changes in both battery capacity and the SOC-OCV curve based on measurements made during charging or discharging events.

### SUMMARY OF THE INVENTION

In accordance with the teachings of the present invention, methods are disclosed for modeling changes in capacity and the state of charge vs. open circuit voltage (SOC-OCV) curve for a battery cell as it ages. During battery pack charging, voltage and current data are gathered for a battery cell. In one method, using multiple data points taken during the plug-in charge event, data optimization is used to determine values for two parameters which define a scaling and a shifting of the SOC-OCV curve from its original shape at the cell's beginning of life to its shape in the cell's current condition. In a second method, only initial and final voltages and current throughput data are needed to determine the values of the two parameters. With the scaling and shifting parameters calculated, the cell's updated capacity and updated SOC-OCV curve can be determined. The methods can also be applied to data taken during a discharge event, such as when a vehicle is driven.

Additional features of the present invention will become apparent from the following description and appended claims, taken in conjunction with the accompanying drawings.

### BRIEF DESCRIPTION OF THE DRAWINGS

FIG. 1 is a graph showing state of charge vs. open circuit voltage (SOC-OCV) curves for a battery cell in both a new condition and an aged condition;

FIG. 2 is a block diagram of a system for determining an updated SOC-OCV curve and capacity for a battery cell, using data from a plug-in charge event or a discharge event;

FIG. 3 is a flowchart diagram of a first method for determining an updated SOC-OCV curve and capacity for a battery cell, using data from a plug-in charge event or a discharge event; and

FIG. 4 is a flowchart diagram of a second method for determining an updated SOC-OCV curve and capacity for a battery cell, using data from a plug-in charge event or a discharge event.

### DETAILED DESCRIPTION OF THE EMBODIMENTS

The following discussion of the embodiments of the invention directed to a method for modeling changes in the state of charge vs. open circuit voltage curve for a battery cell as it ages is merely exemplary in nature, and is in no way intended to limit the invention or its applications or uses. For example, the discussion that follows is directed to battery cells used in electric vehicle battery packs, but the method is equally applicable to battery cells in other vehicular and non-vehicular applications.

Battery packs in electric vehicles and gasoline-electric or diesel-electric hybrid vehicles (hereinafter collectively referred to simply as “electric vehicles”) typically consist of hundreds of individual cells. In one popular lithium-ion rechargeable battery chemistry, each cell produces approximately 3.7 volts nominally, with the exact value depending on state of charge, age and other factors. Many cells connected serially in a module provide the high voltage necessary to drive electric vehicle motors, while multiple cells can be arranged in parallel in cell groups to increase capacity.

In order to manage the charging and discharging of an electric vehicle battery pack, it is important to know the state of charge of the battery cells at all times. State of charge is a number, expressed as a percentage, which indicates how much electrical energy is stored in a battery cell relative to the capacity of the cell. That is, a fully charged battery cell has a state of charge of 100%, while a fully discharged cell has a state of charge of 0%.

State of charge of a cell is typically determined based on the open circuit voltage of the cell, using a known relationship which is defined in the form of a state of charge vs. open circuit voltage (SOC-OCV) curve. Using this relationship, a battery supervisory controller in an electric vehicle can monitor the state of charge of the cells in a battery pack, and hence the state of charge of the overall battery pack, at all times. However, as battery cells age, the energy storage capacity fades to due loss of active material in the electrodes and an increase in internal resistance. The shape of the SOC-OCV curve also changes as a cell ages.

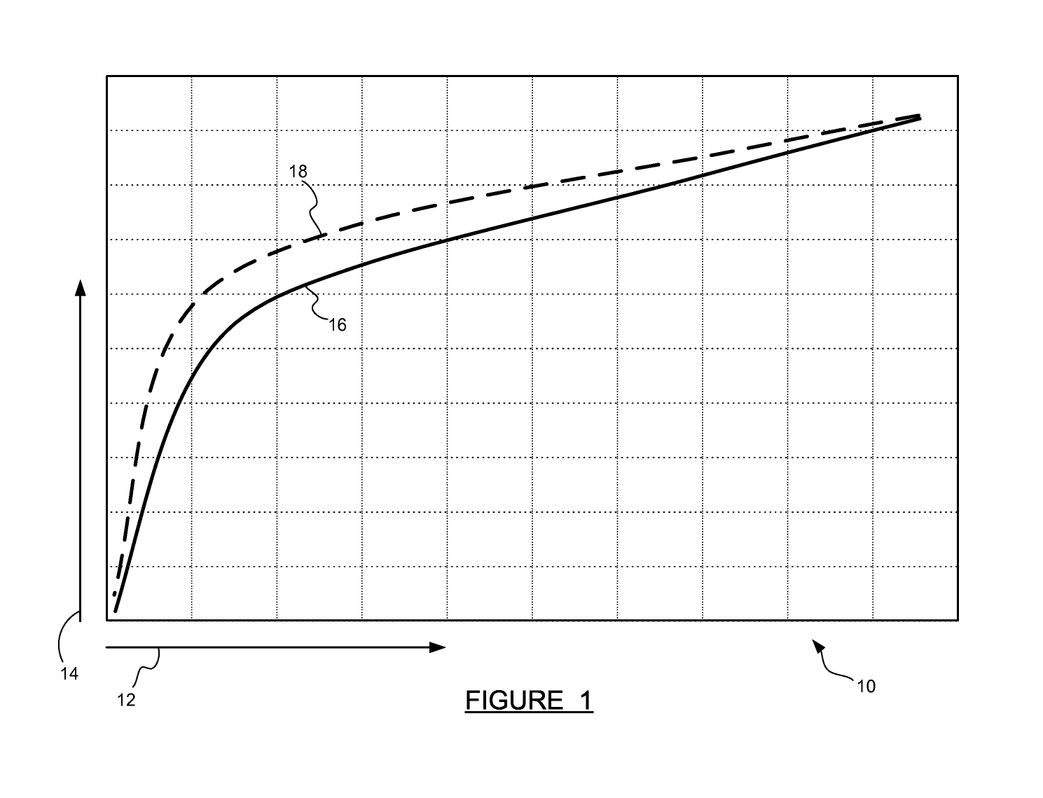

FIG. 1 is a graph 10 showing SOC-OCV curves for a battery cell in both a new condition and an aged condition. Horizontal axis 12 represents state of charge of the battery cell, ranging from 0-100%. Vertical axis 14 represents open circuit voltage of the cell, with values ranging from about 3.0 volts to about 4.0 volts. While the exact shape and scale of SOC-OCV curves vary based on battery chemistry, FIG. 1 is representative of a typical lithium-ion battery cell. Curve 16 depicts the SOC-OCV curve for a battery cell when it is new. Curve 18 depicts the SOC-OCV curve for the same battery cell after it has aged, for example, by experiencing a lifetime of charge-discharge cycles typical of an electric vehicle battery. It can be seen that a state of charge determined based on open circuit voltage from the curve 18 may be significantly different from the state of charge determined from the curve 16, especially in the 5-60% state of charge range. Thus, it is important to understand the changes in the SOC-OCV curve as a battery cell ages, in order to properly manage both charging and discharging operations. It is also important to understand changes in battery cell capacity as the cell ages.

The methods disclosed herein use data collected during a plug-in charge event to specify the SOC-OCV curve in a battery cell's current condition. With the SOC-OCV curve specified, the battery cell capacity can also be determined. The methods can also use data collected during a discharging event, such as a drive cycle of the host electric vehicle.

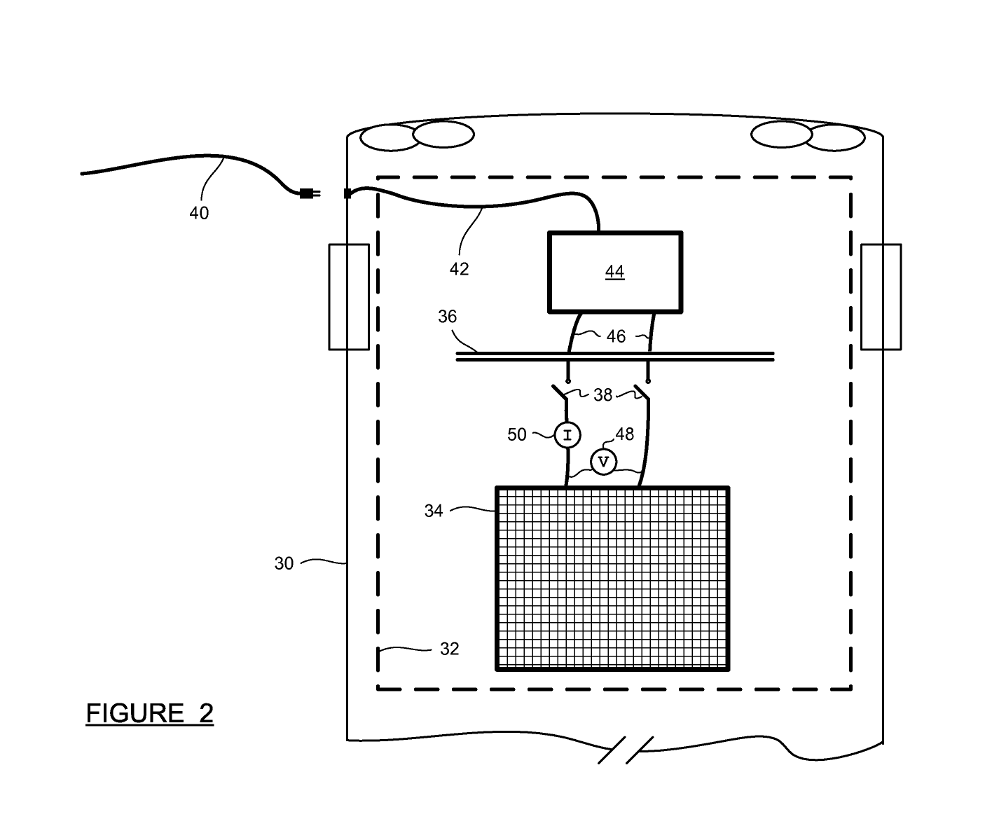

FIG. 2 is a block diagram of a vehicle 30 including a system 32 for specifying the SOC-OCV curve and determining the capacity of cells in a battery pack 34, using data from a plug-in charge event or a discharge event. The battery pack 34 provides power via a high voltage bus 36 to one or more electric motors (not shown) which drive the wheels of the vehicle 30. Contactors 38 electrically connect the battery pack 34 to the high voltage bus 36. The vehicle 30 is an electric or hybrid-electric vehicle which allows plug-in charging of the battery pack 34 via a power cord 40 which is typically connected to the utility power grid. An internal cable 42 routes the charging current to a controller 44, which controls the plug-in charge event and monitors battery pack conditions—such as voltage, current and temperature. In the configuration shown, the controller 44 is also configured to determine the current capacity and SOC-OCV curve of cells in the battery pack 34, using the methods described below. In another configuration, the capacity and SOC-OCV curve calculations could be performed by a second control module (not shown) other than the controller 44.

Positive and negative leads 46 carry the charging current to the battery pack 34, as controlled by the controller 44. A voltmeter 48, in communication with the controller 44, measures terminal voltage of cells in the battery pack 34. A current sensor, or ammeter 50, also in communication with the controller 44, measures charging current during the plug-in charge event, and discharging current during driving of the vehicle 30. Other details of the system 32, not essential to its understanding, are omitted for clarity.

It is to be understood that the controller 44 includes a memory module and a microprocessor or computing device which is configured to perform the calculations discussed in detail below. That is, the methods are to be carried out using a specifically programmed processor, as opposed to on a sheet of paper or in a person's head.

As shown in FIG. 1, a battery cell's SOC-OCV curve changes as the cell ages. However, the characteristic shape of the SOC-OCV curve remains the same. The methods disclosed herein take advantage of the consistent shape of the SOC-OCV curve by identifying a scale factor and a shift value which can be applied to an original SOC-OCV curve to determine an updated SOC-OCV curve.

Consider that a complete battery cell consists of a cathode half-cell and an anode half-cell. The battery cell's open circuit voltage is simply the cathode half-cell's potential minus the anode half-cell's potential. This basic relationship can be written as follows:

V_{oc}=Uₚ(socₚ)−Uₙ(socₙ) (1)

Where V_{oc} is the open circuit voltage of the full battery cell, Uₚ(socₚ) is the open circuit voltage potential of the cathode half-cell at a particular state of charge (denoted by p for positive electrode), and Uₙ(socₙ) is the open circuit voltage potential of the anode half-cell at a particular state of charge (denoted by n for negative electrode).

In a lithium-ion battery cell, the amount of active material decreases as the cell ages, thus causing the anode half-cell's SOC-OCV curve to shift. There is no appreciable change, however, in the cathode half-cell's SOC-OCV curve as the cell ages. These observations can be used in a method to track the changes in the full cell's SOC-OCV curve by modeling a scaling and a shifting of the anode half-cell's SOC-OCV curve. For instance, at the end of a charge event, Equation (1) can be re-written to account for the changes in the SOC-OCV curve as follows:

V_{oc}=Uₚ(soc_{final})−Uₙ(A·soc_{final}+B) (2)

Where V_{oc} is the open circuit voltage of the full battery cell, Uₚ(soc_{final}) is the cathode half-cell potential at the final state of charge, and Uₙ(A·soc_{final}+B is the anode half-cell potential at a state of charge which is both scaled (by a factor A) and shifted (by a term B) from the final state of charge. At this point, socₚ and socₙ have been rescaled to be on the same axis and are both referred to as soc.

Another fundamental principle of a battery cell can be written as follows:

$${soc}_{final} = {soc}_{initial} + \frac{1}{Q} \int I \cdot d t \qquad ( 3 )$$

Where soc_{final} is the final state of charge (at end of a charge event), socᵢₙᵢₜᵢₐₗ is the initial state of charge (at beginning of the charge event), Q is the capacity of the battery cell, and ∫I·dt is the time integral of charging current for the duration of the charge event.

In Equation (3), “final” does not only refer to the end of the plug-in charge event. For the optimization algorithm, multiple time steps, or points of SOC, are needed during the plug-in charge, so this integral is continuously evaluate over different time periods. A “final” SOC is calculated at each time step; for example, socₜ₌₃ has been integrated for 3 seconds.

Using Equations (2) and (3), an algorithm can be created to determine the values of the scale factor A and the shift term B through regression or optimization fitting of multiple data points from a plug-in charge. Beginning from a known, initial state of charge, a series of incremental “final” state of charge data points can be captured during the plug-in charge event. For example, approximately ten data points can be captured during the course of the plug-in charge event. More or fewer than ten data points can also be used. In order for the methods to yield accurate results, it is necessary for the battery cell to begin the plug-in charge event in a rested condition; that is, no significant charging or discharging current over the past hour or more. A rested battery cell is required so that an accurate open circuit voltage can be determined by measuring terminal voltage of the cell. It is also necessary that the battery cell begins the plug-in charge event at a sufficiently low initial state of charge—such as less than 50%—so that the captured data points cover a large portion of the SOC-OCV curve.

As the plug-in charge progresses, data points are collected for the overall cell and the cathode half-cell open-circuit voltages. The cathode half-cell open circuit voltage is an estimate, but it has a negligible degradation rate with cell age. The cathode half-cell open circuit voltage is derived from state of charge estimates using the capacity of a beginning-of-life (BOL) cell over the duration of the plug-in charge. In other words, using Equation (3), a “final” state of charge at any time during the plug-in charge event can be estimated if the initial state of charge, the battery cell capacity and the cumulative charging current are known. From this estimated state of charge, the cathode half-cell open circuit voltage can be determined using known SOC-OCV properties of the cathode half-cell, which do not change as the cell ages. In this way, a series of k data points are collected, each point including a full-cell open circuit voltage, a cathode half-cell open circuit voltage, and cumulative charging current.

The plug-in charge event must run to completion, which occurs at a known cell voltage. When the plug-in charge ends, the actual change in state of charge is calculated for the anode using the SOC determined from integrated current and BOL capacity, and open circuit voltages of the overall cell and of the cathode half-cell. The state of charge associated with the charge termination voltage is known and generally unchanging as the SOC-OCV relationship at high state of charge is not significantly shifted over life. The change of the overall cell's SOC-OCV curve is only affected by the change in the anode SOC-OCV relationship, and can be determined by optimizing the two parameters, A and B, which represent the scale and shift in the cell's state of charge from a BOL cell's capacity to the degraded cell's capacity. A and B then can be used to determine the amount of capacity fade and the degraded cell's overall SOC-OCV curve.

Following is an explanation of the regression or optimization calculations applied to the k data points to determine the values of A and B. Using the full-cell and cathode half-cell open circuit voltages for each point as described above, a vector Y is defined as:

Y=Uₙ⁻¹(Uₚ(soc)−V_{oc})=A·soc+B (4)

Where Y is a 1×k vector (one value for each of the k data points), and the other variables are as defined previously. Two more 1×k vectors—x₁ and x₂—can be defined as:

x₁=[soc(1),soc(2), . . . , soc(k)] (5)

x₂=[1, . . . , 1] (6)

Where the x₁ vector contains the state of charge value for each of the k data points, and the x₂ vector contains all 1's. A matrix X can then be defined as:

X=[x₁^{T},x₂^{T}] (7)

In Equations (4)-(7), only A and B are unknown, given the previously described assumptions about cell capacity and cathode half-cell open circuit voltage. A number of different mathematical optimization techniques can be used to find the values of A and B which provide the optimum fit to the k data points. One technique which can be used is a least-squares estimation, which is defined as:

Θ=(X^{T}·X)⁻¹·X^{T}·Y (8)

Where Θ is a vector containing two elements, θ₁ and θ₂, and where θ₁=A and θ₂=B. With A and B now known for the just-completed plug-in charge event, the updated SOC-OCV curve for the aged battery cell can be determined using Equation 2.

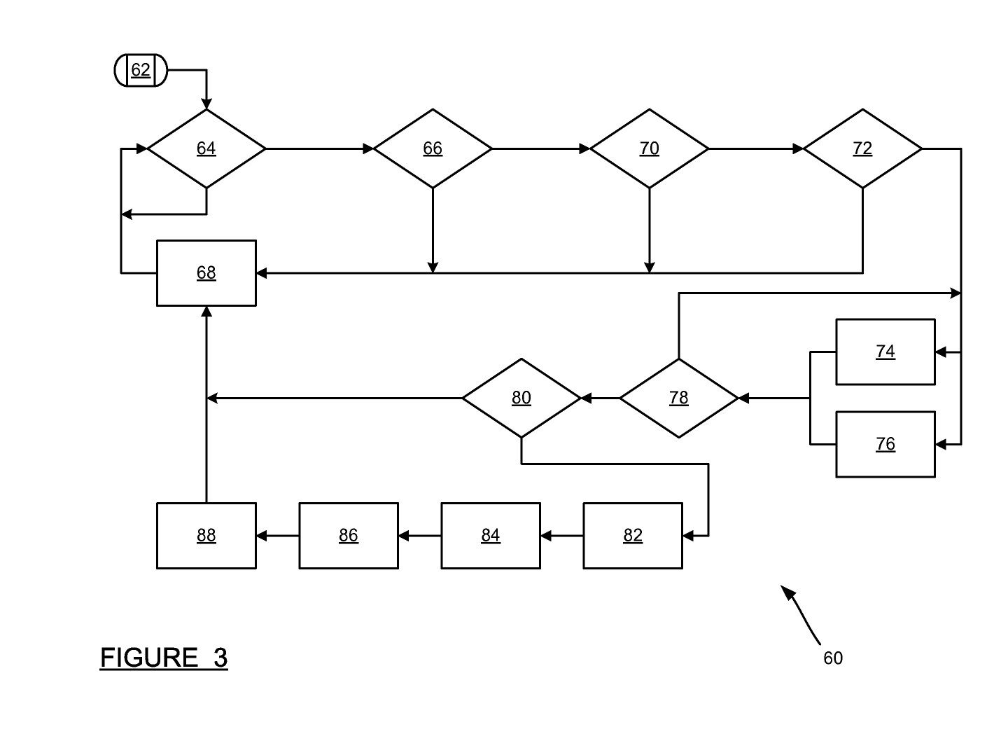

FIG. 3 is a flowchart diagram 60 of a first method for determining an updated SOC-OCV curve and capacity for a battery cell, using data from a plug-in charge event and the techniques described above. The method begins at start oval 62, where an initial (BOL) SOC-OCV curve is provided. At decision diamond 64, it is determined whether the controller 44 is awake. If the controller 44 is not awake, then no charging event or discharging event is possible, and the process loops back until the controller 44 is awake. At decision diamond 66, it is determined if the battery pack 34 is in a rested condition, so that open circuit voltage of one or more cells can be determined from a terminal voltage reading, thus providing an accurate state of charge. If the battery pack 34 is not rested, meaning that the battery pack 34 has experienced a significant charging or discharging recently (for example, within the preceding 1-2 hours), then the process proceeds to box 68 where it waits until the controller 44 goes to sleep.

If, at the decision diamond 66, the battery pack 34 is rested, then at decision diamond 70 it is determined whether the nominal state of charge is low enough (for example, below 50%) to allow the method to be used accurately. In this context, “nominal” means the state of charge of the battery cell based on the baseline (beginning of life) SOC-OCV curve for the cell, which is looked up from the initial, rested open circuit voltage of the battery cell before the plug-in charge event. This determination is based on a terminal voltage reading taken at the decision diamond 70. If the nominal state of charge is not low enough, then the process proceeds to box 68 where it waits until the controller 44 goes to sleep. If the nominal state of charge is low enough at the decision diamond 70, then a plug-in charge event is awaited at decision diamond 72. If no plug-in charge is initiated, then the process proceeds to box 68 where it waits until the controller 44 goes to sleep. When a plug-in charge event begins at the decision diamond 72, data collection begins by estimating open circuit voltages at box 74 and accumulating current throughput at box 76, as discussed previously. This data is stored in the controller 44. At decision diamond 78, it is determined whether the plug-in charge event has ended. If the plug-in charge event has not ended, the process loops back and data collection continues at the boxes 74 and 76. As discussed previously, a plurality of time steps—such as ten, for example—are required during the charge event.

If the plug-in charge event has ended, then at decision diamond 80 it is determined whether the charge was complete—that is, whether the battery cell reached the expected final open circuit voltage. If a large enough change in state of charge was not achieved, then the data is discarded and the process proceeds to box 68 where it waits until the controller 44 goes to sleep. If a full charge was achieved, then at box 82 the state of charge and open circuit voltages are determined for each time step using the voltage data and the integrated current data. At box 84, the fitting of the data points is performed as described previously, to determine the values for A and B. At box 86, the most recent values for A and B are blended with past estimates for A and B, as a means of dampening out variations. Temperature compensation is also included at the box 86, as battery cell SOC-OCV curves vary slightly, and by a known and predictable amount, with temperature. At box 88, the values for A and B are stored by the controller 44 and used with the initial SOC-OCV curve to determine an updated SOC-OCV curve, which is used to compute the state of charge of the battery pack 34 and the driving range of the vehicle 30 in operation.

The method shown in FIG. 3, based on the regression/optimization fitting of multiple data points taken during a plug-in charge event, can also be applied to data points taken during a discharging event, such as driving of the vehicle 30. In the flowchart diagram 60, the following changes would be made to apply the method to discharging; at the decision diamond 70, it would be determined whether the battery is at full charge; at the decision diamond 72, a drive event would be awaited; at the box 76, discharge current throughput would be accumulated; at the decision diamond 78, the end of the drive event would be detected; and at the decision diamond 80, a final state of charge below a threshold (for example, about 50%) would be tested for. That is, for a drive/discharge event, the nature of the calculations remains the same, and the method is applicable as long as the battery cell initially rested and is then discharged from 100% state of charge to a fairly low state of charge.

A second method can also be defined for estimating the updated capacity of a battery cell and the updated SOC-OCV curve for the cell. The second method does not require the collection of multiple data points during a plug-in charge event. Rather, the second method uses only the start and end points of a plug-in charge. However, the second method requires a resting period both before and after the plug-in charge event, so as to allow accurate initial and final open circuit voltage estimates from terminal voltage readings.

The second method, like the first method, is based on the known characteristic of the SOC-OCV curve for the battery cell, where the properties of an aged cell can be defined in terms of a scale factor A and a shift term B applied to an original SOC-OCV curve. As discussed previously, changes to the SOC-OCV curve for an aged battery cell are negligible at full charge. Therefore, it can be stated:

soc_{final}=f(V_{final}^{rested}) (9)

Which means that a final state of charge (after a charge event) can be determined from the final, rested open circuit voltage of the battery cell, using the baseline (beginning of life) SOC-OCV curve for the cell at a given temperature.

Furthermore, a “nominal” initial state of charge can be determined from an initial open circuit voltage reading as follows:

socᵢₙᵢₜ^{nom}=f(Vᵢₙᵢₜ^{rested}) (10)

Where socᵢₙᵢₜ^{nom} is the initial state of charge of the battery cell based on the baseline (beginning of life) SOC-OCV curve for the cell, which is looked up from the initial, rested open circuit voltage of the battery cell before the plug-in charge event.

An estimate of the initial state of charge can also be determined based on the final state of charge and the charge current integral, as follows:

$${soc}_{init}^{est} = {soc}_{final} - \frac{Δ {Q}_{PIC}}{{Q}_{est}} \qquad ( 11 )$$

Where socᵢₙᵢₜ^{est} is the estimated initial state of charge of the battery cell, sco_{final} is the known final state of charge of the cell, ΔQ_{PIC} is the time integral of the charging current for the plug-in charge event (=∫I·dt), and Qₑₛₜ is a recent estimate of battery cell capacity.

Based on the theory described previously, that the SOC-OCV curve of the aged cell can be defined in terms of a scale factor and a shift term applied to the baseline SOC-OCV curve of a new cell, it can be stated that there exist an A and B such that:

∃A,B→socᵢₙᵢₜ^{est}=A·socᵢₙᵢₜ^{nom}+B (12)

and

soc_{final}=A·sco_{final}+B (13)

Where Equations (12) and (13) represent two equations with two unknowns (A and B), which can be solved algebraically. The solution of Equations (12) and (13) are:

$$\begin{matrix}A = \frac{{soc}_{init}^{est} - {soc}_{final}}{{soc}_{init}^{nom} - {soc}_{final}} \\ and & ( 14 ) \\ B = ( 1 - A ) \cdot {soc}_{final} & ( 15 )\end{matrix}$$

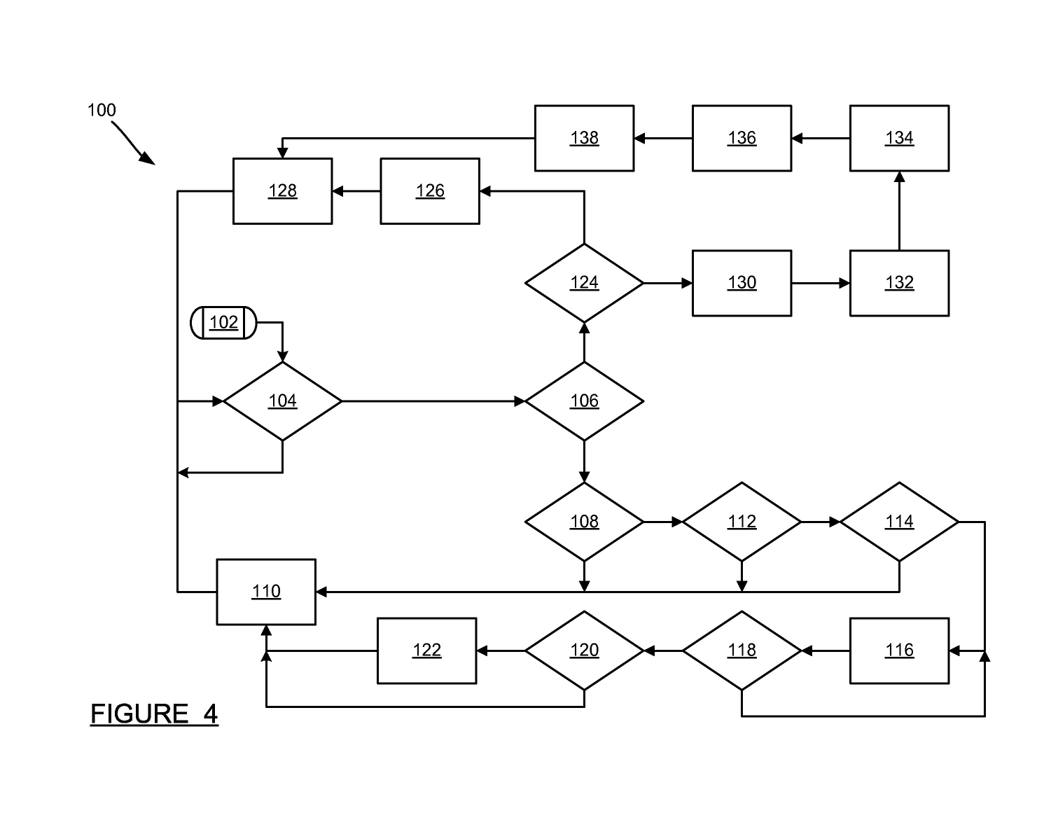

FIG. 4 is a flowchart diagram 100 of a second method for determining an updated SOC-OCV curve and capacity for a battery cell, using data from a plug-in charge event and the techniques described immediately above. The method begins at start oval 102, where an initial (BOL) SOC-OCV curve is provided. At decision diamond 104, it is determined whether the controller 44 is awake. If the controller 44 is not awake, then no charging event or discharging event is possible, and the process loops back until the controller 44 is awake. At decision diamond 106, it is determined whether data for a charge event has been stored over a sleep cycle. If not, then an attempt is made to collect data for a charge event, and at decision diamond 108 it is determined if the battery pack 34 is in a rested condition. If the battery pack 34 is not rested, then the process proceeds to box 110 where it waits until the controller 44 goes to sleep.

If, at the decision diamond 108, the battery pack 34 is rested, then at decision diamond 112 it is determined whether the voltage is low enough (for example, open circuit voltage corresponding to a BOL SOC below 50%) to allow the method to be used accurately. This determination is based on a terminal voltage reading taken at the decision diamond 112. If the voltage is not low enough, then the process proceeds to box 110 where it waits until the controller 44 goes to sleep. If the voltage is low enough at the decision diamond 112, then a plug-in charge event is awaited at decision diamond 114. If no plug-in charge is initiated, then the process proceeds to box 110 where it waits until the controller 44 goes to sleep. When a plug-in charge event begins at the decision diamond 114, data collection begins by accumulating current throughput at box 116, as discussed previously. This data is stored in the controller 44. At decision diamond 118, it is determined whether the plug-in charge event has ended. If the plug-in charge event has not ended, the process loops back and data collection continues at the box 116.

If the plug-in charge event has ended, then at decision diamond 120 it is determined whether the charge was complete. That is, whether the battery cell reached the expected final terminal voltage. If a full charge was not achieved, then the data is discarded and the process proceeds to box 110 where it waits until the controller 44 goes to sleep. If a full charge was achieved, then at box 122 the initial, rested voltage and the current throughput data are stored in the controller 44 over a sleep cycle as the battery pack rests.

At decision diamond 106, if data for a charge event has been stored over a sleep cycle, then at decision diamond 124 it is determined whether the battery is rested, as discussed previously. If the battery is not sufficiently rested, then at box 126 the stored data is cleared from memory, and at box 128 the process waits until the controller 44 goes to sleep. If the battery is sufficiently rested at the decision diamond 124, then at box 130 the final, rested voltage is measured. At box 132, the state of charge values from Equations (9)-(11) are evaluated, using the initial and final, rested voltage data and the current throughput data. At box 134, the two Equations (14) and (15) are solved, to determine the values for A and B. At box 136, the most recent values for A and B are blended with past estimates for A and B, as a means of dampening out variations. Temperature compensation is also included at the box 136. At box 138, the values for A and B are stored by the controller 44 and used with the initial SOC-OCV curve to determine an updated SOC-OCV curve, which is used to compute the state of charge of the battery pack 34 and the driving range of the vehicle 30 in operation.

The method shown in FIG. 4, based on the algebraic calculation of A and B from the start and end data points of a plug-in charge event, can also be applied to a discharging event. In the flowchart diagram 100, the following changes would be made to apply the method to discharging; at the decision diamond 112, it would be determined whether the battery is fully charged; at the decision diamond 114, a drive event would be awaited; at the box 116, discharge current throughput would be accumulated; at the decision diamond 118, the end of the drive event would be detected; and at the decision diamond 120, a nominal (BOL) state of charge below about 50% would be tested for. That is, for a drive/discharge event, the nature of the calculations remains the same, and the method is applicable as long as the battery cell is discharged from a full charge to a fairly low state of charge, and the battery is rested both before and after the discharge event.

Using the methods disclosed herein, the actual performance of a battery cell, in the form of its updated capacity and SOC-OCV curve, can be monitored as the cell ages. Knowledge of the capacity and SOC-OCV curve for cells in a battery pack enables better management of battery pack charging and discharging, increased accuracy of vehicle range predictions, and improved battery pack performance and durability.

The foregoing discussion discloses and describes merely exemplary embodiments of the present invention. One skilled in the art will readily recognize from such discussion and from the accompanying drawings and claims that various changes, modifications and variations can be made therein without departing from the spirit and scope of the invention as defined in the following claims.

What is claimed is:

1. A method for updating a state of charge vs. open circuit voltage curve (SOC-OCV curve) for a battery cell as it ages, said method comprising:
providing an initial SOC-OCV curve for the battery cell;
determining if the battery cell is rested, so that an initial open circuit voltage value can be determined from a terminal voltage reading;
estimating an initial state of charge value from the initial open circuit voltage value, and determining whether the initial state of charge value is below a predetermined threshold before charging or whether the initial state of charge value corresponds to fully charged before discharging;
providing full-cell voltage data and current throughput data for a charge or a discharge of the battery cell, where the data is obtained by sensors;
determining whether the charge of the battery cell reached fully charged or the discharge of the battery cell reached a final state of charge value below the predetermined threshold;
computing, using a microprocessor, a scale factor and a shift value from the voltage data and the current throughput data; and
applying the scale factor and the shift value to the initial SOC-OCV curve to obtain an updated SOC-OCV curve for the battery cell.

2. The method of claim 1 wherein providing full-cell voltage data and current throughput data for a charge or a discharge of the battery cell includes providing full-cell voltage data and current throughput data for a plurality of time steps during the charge or discharge.

3. The method of claim 2 further comprising estimating a state of charge value for each of the time steps from the full-cell voltage data, the current throughput data and an estimated battery cell capacity, and determining a cathode half-cell open circuit voltage value from the state of charge value for each of the time steps.

4. The method of claim 3 wherein computing a scale factor and a shift value from the voltage data and the current throughput data includes performing a regression calculation, using estimated full-cell open circuit voltage data, the cathode half-cell open circuit voltage value and the state of charge value for each of the time steps, to optimize the scale factor and the shift value.

5. The method of claim 1 wherein providing full-cell voltage data and current throughput data for a charge or a discharge of the battery cell includes measuring total current throughput for the charge or discharge, and measuring a final open circuit voltage value after the charge or discharge.

6. The method of claim 5 further comprising allowing the battery cell to rest after the charge or discharge and before measuring the final open circuit voltage value.

7. The method of claim 6 wherein computing a scale factor and a shift value from the open circuit voltage data and the current throughput data includes performing an algebraic calculation using the initial open circuit voltage value, the final open circuit voltage value, the current throughput data and an estimated battery cell capacity, to compute the scale factor and the shift value.

8. The method of claim 1 further comprising calculating an updated capacity for the battery cell based on the updated SOC-OCV curve and the current throughput data.

9. The method of claim 8 wherein the updated SOC-OCV curve and the updated capacity are used to optimize subsequent charging and discharging of the battery cell.

10. The method of claim 1 wherein the battery cell is part of a battery pack which is used in an electric vehicle.

11. A method for updating a state of charge vs. open circuit voltage curve (SOC-OCV curve) for a battery cell as it ages using data from a plug-in charge, said method comprising:
providing an initial SOC-OCV curve for the battery cell;
determining if the battery cell is rested, so that an initial open circuit voltage value can be determined from a terminal voltage reading;
estimating an initial state of charge value from the initial open circuit voltage value, and determining whether the initial state of charge value is below a predetermined threshold before charging;
measuring full-cell voltage data and current throughput data for a plurality of time steps during the plug-in charge of the battery cell, where the data is measured by sensors;
determining whether the plug-in charge of the battery cell reached a fully charged state;
estimating a state of charge value for each of the time steps from the full-cell voltage data, the current throughput data and an estimated battery cell capacity, and determining a cathode half-cell open circuit voltage value from the state of charge value for each of the time steps;
computing, using a microprocessor, a scale factor and a shift value by performing a regression calculation, using the full-cell voltage data, the cathode half-cell open circuit voltage value and the state of charge value for each of the time steps, to optimize the scale factor and the shift value; and
applying the scale factor and the shift value to the initial SOC-OCV curve to obtain an updated SOC-OCV curve for the battery cell.

12. The method of claim 11 further comprising calculating an updated capacity for the battery cell based on the updated SOC-OCV curve and the current throughput data, and using the updated SOC-OCV curve and the updated capacity to optimize subsequent charging and discharging of the battery cell.

13. A method for updating a state of charge vs. open circuit voltage curve (SOC-OCV curve) for a battery cell as it ages using data from a plug-in charge, said method comprising:
providing an initial SOC-OCV curve for the battery cell;
determining if the battery cell is rested, so that an initial open circuit voltage value can be determined from a terminal voltage reading;
estimating an initial state of charge value from the initial open circuit voltage value, and determining whether the initial state of charge value is below a predetermined threshold before charging;
measuring current throughput data during the plug-in charge of the battery cell, where the data is measured by sensors;
determining whether the plug-in charge of the battery cell reached a fully charged state;
allowing the battery cell to rest after the plug-in charge is completed;
measuring a final open circuit voltage value after the plug-in charge;
computing, using a microprocessor, a scale factor and a shift value by performing an algebraic calculation using the initial open circuit voltage value, the final open circuit voltage value, the current throughput data and an estimated battery cell capacity; and
applying the scale factor and the shift value to the initial SOC-OCV curve to obtain an updated SOC-OCV curve for the battery cell.

14. The method of claim 13 further comprising calculating an updated capacity for the battery cell based on the updated SOC-OCV curve and the current throughput data, and using the updated SOC-OCV curve and the updated capacity to optimize subsequent charging and discharging of the battery cell.

15. A system for updating a state of charge vs. open circuit voltage curve (SOC-OCV curve) for a battery cell as it ages, said system comprising:
a voltmeter for measuring voltage data for the battery cell;
an ammeter for measuring current data for the battery cell; and
a controller in communication with the voltmeter and the ammeter, said controller including a processor and a memory, said controller being configured to compute a scale factor and a shift value from the voltage data before, during and after a plug-in charge of the battery cell and the current data during the plug-in charge of the battery cell, where the scale factor and the shift value can be applied to an initial SOC-OCV curve to obtain an updated SOC-OCV curve for the battery cell.

16. The system of claim 15 wherein the controller computes the scale factor and the shift value by recording full-cell voltage data and current throughput data for a plurality of time steps during the plug-in charge, estimating a state of charge value for each of the time steps from the full-cell voltage data, the current throughput data and an estimated battery cell capacity, determining a cathode half-cell open circuit voltage value from the state of charge value for each of the time steps, and performing a regression calculation, using the full-cell voltage data, the cathode half-cell open circuit voltage value and the state of charge value for each of the time steps, to optimize the scale factor and the shift value.

17. The system of claim 15 wherein the controller computes the scale factor and the shift value by measuring a rested initial open circuit voltage value before the plug-in charge, measuring total current throughput for the plug-in charge, measuring a rested final open circuit voltage value after the plug-in charge, and performing an algebraic calculation, using the rested initial open circuit voltage value, the rested final open circuit voltage value, the total current throughput and an estimated battery cell capacity, to compute the scale factor and the shift value.

18. The system of claim 15 wherein the controller is also configured to compute an updated capacity for the battery cell based on the updated SOC-OCV curve and the current data.

19. The system of claim 18 wherein the controller is also configured to use the updated SOC-OCV curve and the updated capacity to optimize subsequent charging and discharging of the battery cell.

20. The system of claim 15 wherein the controller is also configured to compute the updated SOC-OCV curve and an updated capacity using the voltage data and the current data from a discharge event.
